(19) United States
(12) Patent Application Publication
(10) Pub. No.: US 2025/0116712 A1
(43) Pub. Date: Apr. 10, 2025

(54) BATTERY ABNORMALITY DETECTION SYSTEM, BATTERY ABNORMALITY DETECTION METHOD, AND NON-TRANSITORY COMPUTER-READABLE RECORDING MEDIUM

(71) Applicant: Panasonic Intellectual Property Management Co., Ltd., Osaka (JP)

(72) Inventors: Yusuke ITAKURA, Nara (JP); Changhui YANG, Osaka (JP); Shinya NISHIKAWA, Osaka (JP)

(21) Appl. No.: 18/730,494

(22) PCT Filed: Jan. 6, 2023
(86) PCT No.: PCT/JP2023/000192

§ 371 Date: Jul. 19, 2024

(30) Foreign Application Priority Data
Jan. 31, 2022 (JP) 2022-013176

(51) Int. Cl. G01R 31/3835; G01R 31/367; G01R 31/396

(52) U.S. Cl. CPC G01R 31/3835; G01R 31/367; G01R 31/396

(57) ABSTRACT

In a battery abnormality detection system, a data acquirer acquires voltage data and current data of each cell of a battery pack having a plurality of cells connected in series or of each parallel cell block of a battery pack having serially connected parallel cell blocks having a plurality of cells connected in parallel. The abnormality detector detects a cell or parallel cell block in an abnormal state on the basis of a relative voltage change amount among the plurality of cells or among the plurality of parallel cell blocks in a constant voltage charging period.

### CROSS-REFERENCE TO RELATED APPLICATIONS

This application is based upon and claims the benefit of priority from the prior Japanese Patent Application No. 2022-013176, filed on Jan. 31, 2022, and the International Patent Application No. PCT/JP2023/000192, filed on Jan. 6, 2023, the entire content of each of which is incorporated herein by reference.

### BACKGROUND

### Field of the Invention

The present disclosure relates to a battery abnormality detection system, battery abnormality detection method, and battery abnormality detection program for detecting an abnormal state of a battery.

### Description of the Related Art

For EVs or the like, a battery pack including a plurality of parallel cell blocks connected in series, each having a plurality of cells connected in parallel, is often used. In particular, EVs equipped with a large motor include more series of parallel cell blocks. A method has been proposed, in which current is monitored during constant voltage (CV) charging of a battery, and when charging current increases, it is judged that an internal short circuit has occurred (Refer to Patent Literature 1, for example).
Patent Literature 1: JP 2013-254586 A

In a case where the above-described method is applied to a multiple-series cell battery pack, a magnitude of the charging current during the CV charging may be determined by a voltage of a specific parallel cell block. In this case, the charging current basically does not increase even if an internal short circuit occurs in another serially connected parallel cell block. During the CV charging, the charging current is controlled to be reduced so that the voltage of the specific parallel cell block does not rise, and thus an increase in the charging current is reduced.

### SUMMARY OF THE INVENTION

The present disclosure has been devised in view of the above-described circumstances and an object thereof is to provide a technique for easily detecting an abnormal state of a battery pack including a plurality of cells or plurality of parallel cell blocks connected in series.

In order to solve the above-described problem, a battery abnormality detection system according to one aspect of the present disclosure includes: a data acquirer structured to acquire voltage data and current data of each cell of a battery pack having a plurality of cells connected in series or of each parallel cell block of a battery pack having serially connected parallel cell blocks having a plurality of cells connected in parallel; and an abnormality detector structured to detect a cell or parallel cell block in an abnormal state on the basis of a relative voltage change amount among the plurality of cells or among the plurality of parallel cell blocks in a constant voltage charging period.

It should be noted that any combination of the above components, and the expression of the present disclosure converted between a method, an apparatus, a system, a recording medium, a computer program, and the like are also effective as an aspect of the present disclosure.

Embodiments will now be described, by way of example only, with reference to the accompanying drawings which are meant to be exemplary, not limiting, and wherein like elements are numbered alike in several Figures, in which:

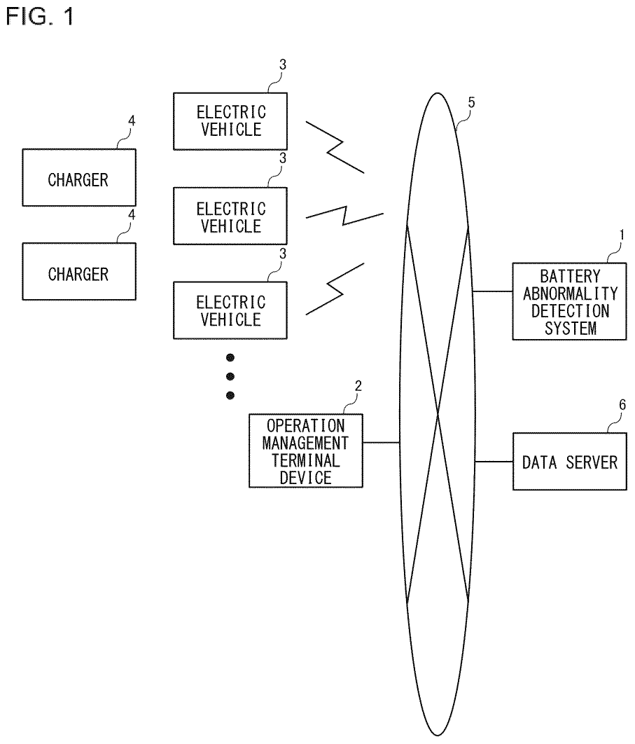

FIG. 1 is a diagram for describing a battery abnormality detection system according to an embodiment.

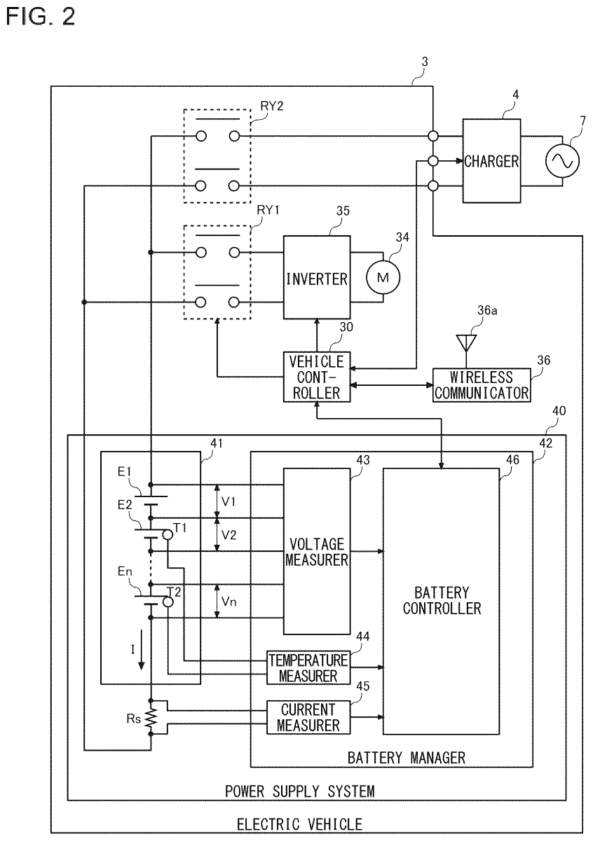

FIG. 2 is a diagram for describing a detailed configuration of a power supply system mounted on an electric vehicle.

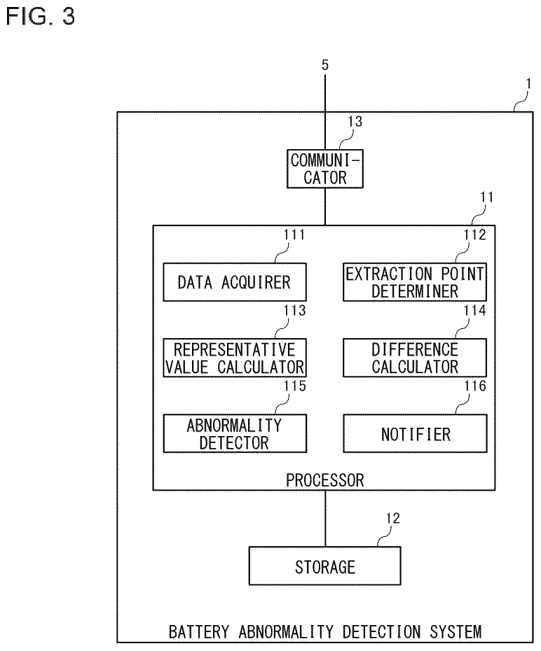

FIG. 3 is a diagram showing a configuration example of the battery abnormality detection system according to the embodiment.

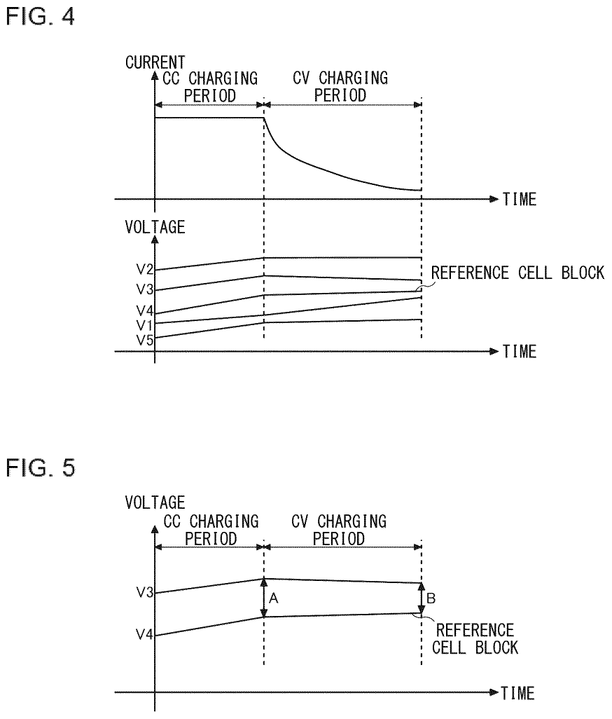

FIG. 4 is a diagram showing an example of time-series data of current and voltage of a battery pack including a plurality of parallel cell blocks.

FIG. 5 is a diagram for describing a definition of a judgment score.

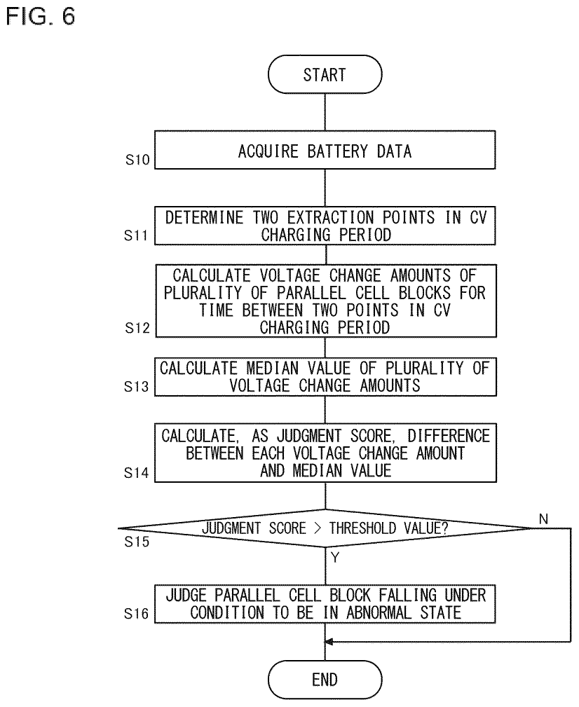

FIG. 6 is a flowchart showing a flow of abnormality detection processing by the battery abnormality detection system according to the embodiment.

### DETAILED DESCRIPTION OF THE INVENTION

The invention will now be described by reference to the preferred embodiments. This does not intend to limit the scope of the present invention, but to exemplify the invention.

FIG. 1 is a diagram for describing a battery abnormality detection system 1 according to an embodiment. The battery abnormality detection system 1 according to the embodiment is a system utilized by at least one delivery service provider. The battery abnormality detection system 1 may be constructed, for example, on an own server installed in a data center of, or installed in an own facility of a provider that provides a battery state analysis service of a battery pack 41 (refer to FIG. 2) mounted on an electric vehicle 3. In addition, the battery abnormality detection system 1 may be constructed on a cloud server utilized under a cloud service contract. In addition, the battery abnormality detection system 1 may be constructed on a plurality of servers dispersedly installed at a plurality of sites (data center, own facility). The plurality of servers may be any one of a combination of a plurality of own servers, a combination of a plurality of cloud servers, or a combination of an own server and a cloud server.

A network 5 is a general term for communication paths such as the Internet, a dedicated line, and a virtual private network (VPN), and a communication medium and protocol thereof are not limited. As the communication medium, for example, a mobile phone network (cellular network), a wireless LAN, a wired LAN, an optical fiber network, an ADSL network, a CATV network, or the like can be used. As the communication protocol, for example, Transmission Control Protocol (TCP)/Internet Protocol (IP), User Datagram Protocol (UDP)/IP, Ethernet (registered trademark), or the like can be used.

The delivery service provider has a plurality of electric vehicles 3 and a plurality of chargers 4, and utilizes the plurality of electric vehicles 3 in a delivery business. Note that the electric vehicles 3 can also be charged from a charger other than the chargers 4 installed at a delivery base. The delivery service provider has a delivery base for parking the electric vehicle 3. An operation management terminal device 2 is installed at the delivery base. The operation management terminal device 2 includes, for example, a PC. The operation management terminal device 2 is used to manage the plurality of electric vehicles 3 belonging to the delivery base.

The operation management terminal device 2 can access the battery abnormality detection system 1 via the network 5 and utilize a state analysis service of the battery pack 41 mounted on the electric vehicle 3. In a state where the electric vehicle 3 is parked at the delivery base, a vehicle controller 30 of the electric vehicle 3 (refer to FIG. 2) and the operation management terminal device 2 can exchange data via the network 5 (a wireless LAN, for example), a CAN cable, or the like. The vehicle controller 30 and the operation management terminal device 2 may also be configured to be able to exchange data via the network 5 while the electric vehicle 3 is traveling.

A data server 6 acquires and accumulates battery data from the operation management terminal device 2 or the electric vehicle 3. The data server 6 may be an own server installed in a data center or an own facility of the delivery service provider or battery state analysis service provider, or may be a cloud server utilized by the delivery service provider or the battery state analysis service provider. In addition, each of the delivery service providers and the battery state analysis service provider may have the data server 6.

FIG. 2 is a diagram for describing a detailed configuration of a power supply system 40 mounted on the electric vehicle 3. The power supply system 40 is connected to a motor 34 via a first relay RY1 and an inverter 35. During power running, the inverter 35 converts direct-current power supplied from the power supply system 40 into alternating-current power and supplies the alternating-current power to the motor 34. During regeneration, the alternating-current power supplied from the motor 34 is converted into direct-current power and supplied to the power supply system 40. The motor 34 is a three-phase alternating-current motor, and, during power running, rotates in accordance with alternating-current power supplied from the inverter 35. During regeneration, rotational energy due to deceleration is converted into alternating-current power and supplied to the inverter 35.

The vehicle controller 30 is a vehicle electronic control unit (ECU) that controls the entire electric vehicle 3, and may include, for example, an integrated vehicle control module (VCM). A wireless communicator 36 includes a modem and performs wireless signal processing for wirelessly connecting to the network 5 via an antenna 36a. As a wireless communication network to which the electric vehicle 3 can be wirelessly connected, for example, a mobile phone network (cellular network), a wireless LAN, a vehicle-to-infrastructure (V2I), a vehicle-to-vehicle (V2V), an electronic toll collection system (ETC system), and dedicated short range communications (DSRC) can be used.

The first relay RY1 is a contactor inserted between wiring connecting the power supply system 40 and the inverter 35. During traveling, the vehicle controller 30 controls the first relay RY1 to be in an on state (closed state) and electrically connects the power supply system 40 and a power system of the electric vehicle 3. During non-traveling, in principle, the vehicle controller 30 controls the first relay RY1 to be in an off state (open state) and electrically disconnects the power supply system 40 and the power system of the electric vehicle 3. Note that, instead of the relay, another type of switch such as a semiconductor switch may be used.

By connecting the electric vehicle 3 to the charger 4, the battery pack 41 in the power supply system 40 can be charged from outside. The charger 4 is connected to a commercial power system 7 and charges the battery pack 41 in the electric vehicle 3. In the electric vehicle 3, a second relay RY2 is inserted between wirings connecting the power supply system 40 and the charger 4. Note that, instead of the relay, another type of switch such as a semiconductor switch may be used. Directly or via the vehicle controller 30, a battery manager 42 controls the second relay RY2 to be turned on before start of charging, and controls the second relay RY2 to be turned off after end of the charging. In general, charging is performed with

alternating current in a case of normal charging, and with direct current in a case of fast charging. In a case where the charging is performed with alternating current (single-phase 100/200 V, for example), alternating-current power is converted into direct-current power by an AC/DC converter (not shown) inserted between the second relay RY2 and the battery pack 41. In a case where the charging is performed with direct current, the charger 4 generates direct-current power by performing full-wave rectification on alternating-current power supplied from the commercial power system 7, and then smoothing the rectified direct current with a filter.

As a fast-charging standard, for example, CHAdeMO (registered trademark), ChaoJi, GB/T, and Combo (Combined Charging System) can be used. In CHAdeMO 2.0, maximum output (specification) is specified at 1000 V×400 A=400 kW. In CHAdeMO 3.0, maximum output (specification) is specified at 1500 V×600 A=900 kW. In ChaoJi, maximum output (specification) is specified at 1500 V×600 A=900 kW. In GB/T, maximum output (specification) is specified at 750 V×250 A=185 kW. In Combo, maximum output (specification) is specified at 900 V×400 A=350 KW. In CHAdeMO, ChaoJi, and GB/T, a controller area network (CAN) is adopted as a communication system. In Combo, power line communication (PLC) is adopted as a communication system.

A charging cable adopting the CAN system includes a communication line in addition to a power line. When the electric vehicle 3 and the charger 4 are connected by the charging cable, the vehicle controller 30 establishes a communication channel with a controller of the charger 4. Note that, in a charging cable adopting the PLC system, a communication signal is superimposed on a power line and transmitted.

The vehicle controller 30 establishes a communication channel with the battery manager 42 via an in-vehicle network (CAN or Local Interconnect Network (LIN), for example). In a case where a communication standard used between the vehicle controller 30 and the controller of the charger 4 is different from a communication standard used between the vehicle controller 30 and the battery manager 42, the vehicle controller 30 has a gateway function.

The power supply system 40 mounted on the electric vehicle 3 includes the battery pack 41 and the battery manager 42. The battery pack 41 includes a plurality of cells E1-En or a plurality of parallel cell blocks. As the cells, a lithium-ion battery cell, a nickel-hydrogen battery cell, a lead battery cell, or the like can be used. Hereinafter in this specification, a case where an example lithium-ion battery cells (nominal voltage: 3.6-3.7 V) are used is assumed. The number of series of the cells E1-En or of the parallel cell blocks is determined according to drive voltage of the motor 34.

A shunt resistor Rs is connected in series with the plurality of cells E1-En or the plurality of parallel cell blocks. The shunt resistor Rs functions as a current detection element. Note that a Hall element may be used instead of the shunt resistor Rs. A plurality of temperature sensors T1, T2 for detecting temperatures of the plurality of cells E1-En or the plurality of parallel cell blocks is installed in the battery pack 41. For example, thermistors can be used as the temperature sensors T1, T2. For example, one temperature sensor may be provided for each six to eight cells or each six to eight parallel cell blocks.

The battery manager 42 includes a voltage measurer 43, a temperature measurer 44, a current measurer 45, and a battery controller 46. A plurality of voltage lines connects respective nodes of the plurality of cells E1-En or plurality of parallel cell blocks connected in series, and the voltage measurer 43. The voltage measurer 43 measures each voltage between two adjacent voltage lines to measure voltages V1-Vn of each of the cells E1-En or of each of the parallel cell blocks. The voltage measurer 43 transmits the measured voltages V1-Vn of the respective cells E1-En or parallel cell blocks to the battery controller 46.

Because the voltage measurer 43 has a higher voltage than the battery controller 46, the voltage measurer 43 and the battery controller 46 are insulated from each other and connected by a communication line. The voltage measurer 43 can include an application specific integrated circuit (ASIC) or a general-purpose analog front-end IC. The voltage measurer 43 includes a multiplexer and an A/D converter. The multiplexer outputs voltages between two adjacent voltage lines to the A/D converter in order from a top. The A/D converter converts analog voltages input from the multiplexer into digital values.

The temperature measurer 44 includes voltage-dividing resistors and an A/D converter. The A/D converter sequentially converts a plurality of analog voltages, each of which is obtained by being divided by the plurality of temperature sensors T1, T2 and the plurality of voltage-dividing resistors, into digital values and outputs the digital values to the battery controller 46. The battery controller 46 measures temperatures of a plurality of observation points in the battery pack 41 on the basis of the plurality of digital values.

The current measurer 45 includes a differential amplifier and an A/D converter. The differential amplifier amplifies a voltage across the shunt resistor Rs and outputs the amplified voltage to the A/D converter. The A/D converter converts an analog voltage input from the differential amplifier into a digital value and outputs the digital value to the battery controller 46. The battery controller 46 measures a current I flowing through the plurality of cells E1-En or the plurality of parallel cell blocks on the basis of the digital value.

Note that, in a case where an A/D converter is mounted in the battery controller 46 and an analog input port is installed in the battery controller 46, the temperature measurer 44 and the current measurer 45 may output the analog voltage to the battery controller 46, and the A/D converter in the battery controller 46 may convert the analog voltage into a digital value.

The battery controller 46 manages states of the plurality of cells E1-En or plurality of parallel cell blocks on the basis of voltages, temperatures, and currents of the plurality of cells E1-En or of the plurality of parallel cell blocks, the voltages, temperatures, and currents being measured by the voltage measurer 43, the temperature measurer 44, and the current measurer 45. When overvoltage, undervoltage, overcurrent, or temperature abnormality occurs in at least one of the plurality of cells E1-En or plurality of parallel cell blocks, the battery controller 46 turns off the second relay RY2 or a protection relay (not shown) in the battery pack 41 to protect the cell or the parallel cell block.

The battery controller 46 can include a microcontroller and a nonvolatile memory (electrically erasable programmable read-only memory (EEPROM) or flash memory, for example). The battery controller 46 estimates a state of charge (SOC) of each of the plurality of cells E1-En or plurality of parallel cell blocks.

The battery controller 46 estimates the SOCs with a combination of an open circuit voltage (OCV) method and a current integration method. The OCV method is a method for estimating an SOC on the basis of an OCV of each cell measured by the voltage measurer 43 and an SOC-OCV curve of the cell. The SOC-OCV curve of the cell is created in advance on the basis of a characteristic test by a battery manufacturer, and is registered in an internal memory of the microcontroller at a time of shipment.

The current integration method is a method for estimating an SOC on the basis of an OCV at a start of charging/discharging of each cell, and of an integrated value of a current measured by the current measurer 45. In the current integration method, measurement errors of the current measurer 45 accumulates as a charge/discharge time becomes longer. Meanwhile, the OCV method is affected by a measurement error of the voltage measurer 43 and an error due to polarization voltage. Therefore, it is preferable to use a weighted average of the SOC estimated by the current integration method and the SOC estimated by the OCV method.

The battery controller 46 periodically (an interval of 10 seconds, for example) samples the battery data including a voltage, current, temperature, and SOC of each of the cells E1-En or of each of the parallel cell blocks, and transmits the battery data to the vehicle controller 30 via the in-vehicle network. The vehicle controller 30 can transmit the battery data to the data server 6 in real time by using the wireless communicator 36 while the electric vehicle 3 is traveling.

In addition, the vehicle controller 30 may accumulate the battery data of the electric vehicle 3 in an internal memory and collectively transmit the battery data accumulated in the memory at a predetermined timing. For example, the vehicle controller 30 may be periodically activated while the electric vehicle 3 is parked, and collectively transmit the battery data accumulated in the memory to the data server 6 by using the wireless communicator 36. In addition, the vehicle controller 30 may collectively transmit the battery data accumulated in the memory to the operation management terminal device 2 after business hours of a day. The operation management terminal device 2 collectively transmits the battery data of the plurality of electric vehicles 3 to the data server 6 at a predetermined timing. In addition, at a time during charging from the charger 4, the vehicle controller 30 may collectively transmit the battery data accumulated in the memory to a charger 4 having a network communication function, via a charging cable. The charger 4 having the network communication function transmits the received battery data to the data server 6. This example is effective for the electric vehicle 3 not equipped with a wireless communication function.

FIG. 3 is a diagram showing a configuration example of the battery abnormality detection system 1 according to the embodiment. The battery abnormality detection system 1 includes a processor 11, a storage 12, and a communicator 13. The communicator 13 is a communication interface (for example, network interface card: NIC) for wired or wireless connection to the network 5.

The processor 11 includes a data acquirer 111, an extraction point determiner 112, a representative value calculator 113, a difference calculator 114, an abnormality detector 115, and a notifier 116. Functions of the processor 11 can be achieved by cooperation of hardware resources and software resources, or by solely hardware resources. As the hardware resources, a CPU, a ROM, a RAM, a graphics processing unit (GPU), an application specific integrated circuit (ASIC), a field programmable gate array (FPGA), and other LSIs can be utilized. Programs such as an operating system and an application can be utilized as the software resources. The storage 12 includes a nonvolatile recording medium such as an HDD or an SSD, and stores various data.

From the data server 6, the data acquirer 111 acquires battery data of a specific battery pack 41 mounted on the electric vehicle 3. The battery data is time-series data including at least voltage data and current data of each cell or each parallel cell block of the specific battery pack 41.

The extraction point determiner 112 determines two extraction points in a CV charging period from the acquired time-series data of the voltage data and current data. In general, the battery pack 41 is charged by a constant current, constant voltage (CCCV) system. The CCCV system is a system in which charging is performed at a constant current before a voltage of the battery pack 41 reaches a set voltage (for example, about 4 V in terms of one cell or one parallel cell block), and charging is performed at a constant voltage after the voltage reaches the set voltage. The charger 4 or a converter in the electric vehicle 3 performs control so that a charging current value maintains a target current value during constant current charging of the battery pack 41, and performs control so that a charging voltage value maintains a target voltage value during constant voltage charging of the battery pack 41.

In the present embodiment, the extraction point determiner 112 determines a CV charging start time point and a CV charging end time point as two extraction points in the CV charging period. For example, the extraction point determiner 112 identifies a charging period on the basis of positive/negative of the current data, and determines a time point, as the CV charging start time point, at which current data at a target time in the charging period decreases from the current data at a reference time (3 minutes before, for example) by a set value or more.

For example, after start of the CV charging period, the extraction point determiner 112 determines a time point at which the current data reaches zero as the CV charging end time point. In addition, the extraction point determiner 112 may determine a time point at which the current data at the target time in the CV charging period becomes the same as the current data at the reference time (3 minutes before, for example) as a substantial end time point of the CV charging period.

Note that the extraction point determiner 112 does not necessarily need to determine the two extraction points in the CV charging period as the CV charging start time point and the CV charging end time point. For example, the extraction point determiner 112 may extract a time point after a set time (3 to 5 minutes) from a CV charging start time instead of the CV charging end time point.

The representative value calculator 113 calculates a representative value of an amount of change in voltage of the plurality of cells or plurality of parallel cell blocks included in the battery pack 41, on the basis of an amount of change in voltage of each of the plurality of cells or plurality of parallel cell blocks for a time between the two points in the CV charging period, the two points being determined by the extraction point determiner 112. The representative value calculator 113 uses, as the representative value, a median value of an amount of change in voltage of the plurality of cells or plurality of parallel cell blocks. Note that the representative value calculator 113 may use, as the representative value, a mean value of the amount of change in voltage of the plurality of cells or plurality of parallel cell blocks, the mean value being obtained by excluding a maximum value and minimum value from the change in voltage.

The difference calculator 114 calculates a difference value (judgment score) between the amount of change in voltage of each of the plurality of cells or plurality of parallel cell blocks and the representative value of the voltage change amount calculated by the representative value calculator 113. That is, the difference calculator 114 extracts an individual factor of each cell or each average cell block by subtracting the representative value of the voltage change amount from the amount of change in voltage of each to remove influence of a standard voltage change for the time between the two points in the CV charging period.

The abnormality detector 115 detects a cell or parallel cell block in an abnormal state on the basis of a relative voltage change amount among the plurality of cells or among the plurality of parallel cell blocks for the time between the two points in the CV charging period. Specifically, the abnormality detector 115 judges a cell or parallel cell block having a voltage drop amount relative to the representative value of the voltage change amount exceeding a threshold value to be a cell or parallel cell block in an abnormal state, having a high internal resistance.

A measured voltage at a time during charging (closed circuit voltage: CCV) is represented by the following (Mathematical formula 1).

$$C C V = OCV + IR \qquad ( Mathematical formula 1 )$$

Because charging current I between the plurality of cells or plurality of parallel cell blocks connected in series is equal, if it is assumed that OCVs of the plurality of cells or plurality of parallel cell blocks are equal, variation in internal resistance R is reflected in the CCV. Because the charging current I decreases in the CV charging period, a voltage component based on IR dynamically changes, unlike in a CC charging period.

In addition, in the CC charging period, the SOC at a start and end of the CC charging greatly changes, and the OCV also greatly changes. Meanwhile, in the CV charging period, the change in the SOC between the start and end of the CV charging is small, and the change in the OCV is also small. Due to these factors, the variation in the internal resistance R can be detected with high accuracy by relatively comparing the amount of change in the CCV during the CV charging period among the plurality of cells or plurality of parallel cell blocks connected in series. In particular, because the charging current I decreases during the CV charging period, it is easy to detect a cell or parallel cell block having a relatively high internal resistance R.

A designer determines the threshold value on the basis of transition data of the above-described judgment score of at least one battery pack 41 with which an unsafe event (thermal runaway, for example) has occurred. In a case where the transition data of judgment scores of the plurality of battery packs 41 with which an unsafe event has occurred is collected, the transition data of the plurality of judgment scores is combined to generate standard data, and the above-described threshold value is determined on the basis of the standard data. Note that, by type or model number of the battery packs 41 with which the unsafe event has occurred, the designer may collect the transition data of the judgment scores of the battery packs 41, and determine the above-described threshold value for each type or model number.

The threshold value is set to a value at a time point temporally before the value at the time point when the unsafe event of the judgment score occurs. As a result, a sign of occurrence of an unsafe event can be detected.

In a case where the specific battery pack 41 mounted on the electric vehicle 3 includes a cell or parallel cell block in an abnormal state, the notifier 116 notifies the electric vehicle 3 or the operation management terminal device 2 of an alert via the network 5. A message prompting inspection, repair, or replacement is added to the alert notification.

FIG. 4 is a diagram showing an example of time-series data of current and voltage of the battery pack 41 including a plurality of parallel cell blocks. The example shown in FIG. 4 shows time-series data of current and voltage of the battery pack 41 including five parallel cell blocks connected in series. When the CC charging period is switched to the CV charging period, the charging current decreases. From among amounts of change in voltage V1 to V5 of five parallel cell blocks in the CV charging period, a parallel cell block (a fourth parallel cell block in FIG. 4) having a median value is selected as a reference cell block.

FIG. 5 is a diagram for describing a definition of the judgment score. A voltage difference between each parallel cell block and the reference cell block is taken at the CV charging start time point and at the CV charging end time point, and then a value obtained by subtracting a voltage difference B at the CV charging end time point from a voltage difference A at the CV charging start time point is set as the judgment score (A-B). In FIG. 5, a judgment score of a third parallel cell block is calculated. It is indicated that the higher the judgment score, the larger the value of a relative internal resistance among the parallel cell blocks connected in series. In the example shown in FIGS. 4 and 5, the third parallel cell block is judged to be in an abnormal state.

FIG. 6 is a flowchart showing a flow of abnormality detection processing by the battery abnormality detection system 1 according to the embodiment. From the data server 6, the data acquirer 111 acquires battery data of the specific battery pack 41 mounted on the electric vehicle 3 (S10). The extraction point determiner 112 determines two extraction points in the CV charging period from the acquired time-series data of the voltage data and current data (S11). The representative value calculator 113 calculates a median value of a plurality of voltage change amounts of the plurality of parallel cell blocks included in the battery pack 41, for the time between the two points in the CV charging period (S13).

The difference calculator 114 calculates, as the judgment score, a difference value between each voltage change amount of the plurality of parallel cell blocks and the median value (S14). The abnormality detector 115 judges a parallel cell block having a judgment score exceeding the threshold value (Y in S15) to be in an abnormal state (S16). A parallel cell block having a judgment score not exceeding the threshold value (N in S15) is judged to be in a normal state.

In the above description, an example has been described in which a cell or parallel cell block having a judgment score exceeding the threshold value for detecting a high resistance state is judged to be in an abnormal state. In this regard, a cell or parallel cell block having a judgment score lower than a threshold value for detecting a low resistance state (hereinafter, referred to as a second threshold value) for detecting a low resistance state may also be judged to be in an abnormal state.

For example, the designer determines the second threshold value on the basis of transition data of the above-described judgment score of at least one battery pack 41 in which a micro short circuit has occurred in a cell or parallel cell block or a cell failure has occurred in a parallel cell block. A failed cell is a cell having a malfunction, and the cell failure occurs due to opening of a gas release valve, actuation of a current interrupt device (CID), disconnection, contact failure, or the like. Internal resistance decreases in a cell or parallel cell block in which a micro short circuit has occurred, or in a parallel cell block in which a cell failure has occurred.

The abnormality detector 115 judges a cell or parallel cell block having an amount of voltage rise relative to the representative value of the voltage change amount exceeding the second threshold value to be a cell or parallel cell block in an abnormal state, having a low internal resistance.

As described above, in the present embodiment, an abnormal state of a battery pack 41 can be easily detected by calculating a relative voltage change amount among the plurality of cells or plurality of parallel cell blocks connected in series in the CV charging period. An abnormal state of the battery pack 41 can be detected in a case where CV charging is performed with reference to a voltage across the battery pack 41, or in a case where CV charging is performed with reference to a voltage of a specific cell or specific parallel cell block. In particular, it is possible to detect with high accuracy a cell or parallel cell block having a high internal resistance that causes an increase in a relative amount of voltage drop.

In the present embodiment, by using the median value as the representative value, it is possible to remove influence of outliers that may be included in the plurality of voltage change amounts, by which a highly accurate representative value can be easily determined. In the present embodiment, complicated statistical calculation is unnecessary, and an abnormal state of a battery pack 41 can be detected with simple calculation. Therefore, presence or absence of abnormality in a large number of battery packs 41 can be diagnosed at high speed.

The present disclosure has been described above on the basis of the embodiments. It is to be understood by those skilled in the art that the embodiment is merely an example, that various modifications can be made to combinations of the respective components and the respective processing processes, and that such modifications are also within the scope of the present disclosure.

The amount of change in voltage of each cell or each parallel cell block includes an amount of change in voltage due to an external resistance component (wiring resistance, contact resistance, or the like, for example) in addition to an amount of change in voltage caused by an internal resistance component (an electrolytic solution component or the like, for example) of each cell or each parallel cell block. External resistance components among the plurality of cells or plurality of parallel cell blocks connected in series often have variations. Meanwhile, a correction value for each cell or each parallel cell block may be prepared in advance in order to equalize the voltage change due to the external resistance components. The representative value calculator 113 and the difference calculator 114 use the amount of change in voltage of each cell or each parallel cell block corrected with the correction value for each cell or each parallel cell block.

In the above-described embodiment, an example has been described in which an abnormal state of a battery pack 41 mounted on the electric vehicle 3 is detected by the battery abnormality detection system 1 connected to the network 5. In this regard, the battery abnormality detection system 1 may be incorporated in the battery controller 46. In addition, the battery abnormality detection system 1 may be incorporated in the charger 4.

The battery abnormality detection system 1 according to the present disclosure is not limited to use in detecting an abnormal state of the battery pack 41 mounted on the electric vehicle 3. For example, the present invention is also applicable to abnormality detection of a battery pack mounted on an electric ship, a multi-copter (drone), an electric motorcycle, an electric bicycle, a stationary power storage system, a smartphone, a tablet terminal, a notebook PC, and the like.

Note that the embodiment may be specified by the following items.

### Item 1

A battery abnormality detection system (1) including:
a data acquirer (111) structured to acquire voltage data and current data of each cell (E1-En) of a battery pack (41) having a plurality of cells (E1-En) connected in series or of each parallel cell block of a battery pack (41) having serially connected parallel cell blocks having a plurality of cells connected in parallel; and
an abnormality detector (115) structured to detect a cell or parallel cell block in an abnormal state on the basis of a relative voltage change amount among the plurality of cells (E1-En) or among the plurality of parallel cell blocks in a constant voltage charging period.

Thus, it is possible to easily detect the abnormal state of the battery pack (41) including the plurality of cells (E1-En) or plurality of parallel cell blocks connected in series.

### Item 2

The battery abnormality detection system (1) according to Item 1, further including:
a representative value calculator (113) structured to calculate a representative value of an amount of change in voltage of the plurality of cells (E1-En) or of the plurality of parallel cell blocks on the basis of each voltage change amount of the plurality of cells (E1-En) or the plurality of parallel cell blocks for a time between two points in the constant voltage charging period; and
a difference calculator (114) structured to calculate a difference value between each voltage change amount of the plurality of cells (E1-En) or of the plurality of parallel cell blocks, and a representative value of the voltage change amount,
in which the abnormality detector (115) is structured to judge, to be in an abnormal state, a cell or parallel cell block having a voltage drop amount relative to the representative value of the voltage change amount exceeding a threshold value.

Thus, it is possible to detect with high accuracy a cell or parallel cell block having relatively a high internal resistance.

### Item 3

The battery abnormality detection system (1) according to Item 2, in which the representative value calculator (113) is structured to use, as the representative value, a median value of a voltage change amount of the plurality of cells (E1-En) or a median value of a voltage change amount of the plurality of parallel cell blocks.

Thus, it is possible to remove influence of outliers, by which a highly accurate representative value can be easily determined.

### Item 4

A battery abnormality detection method including:
a step of acquiring voltage data and current data of each cell of a battery pack (41) having a plurality of cells (E1-En) connected in series or of each parallel cell block of a battery pack (41) having serially connected parallel cell blocks having a plurality of cells (E1-En) connected in parallel; and
a step of detecting a cell (E1-En) or parallel cell block in an abnormal state on the basis of a relative voltage change amount among the plurality of cells (E1-En) or among the plurality of parallel cell blocks in a constant voltage charging period.

Thus, it is possible to easily detect the abnormal state of the battery pack (41) including the plurality of cells (E1-En) or plurality of parallel cell blocks connected in series.

### Item 5

A battery abnormality detection program for causing a computer to execute processing including:
acquiring voltage data and current data of each cell (E1-En) of a battery pack (41) having a plurality of cells (E1-En) connected in series or of each parallel cell block of a battery pack (41) having serially connected parallel cell blocks having a plurality of cells connected in parallel; and
detecting a cell (E1-En) or parallel cell block in an abnormal state on the basis of a relative voltage change amount among the plurality of cells (E1-En) or among the plurality of parallel cell blocks in a constant voltage charging period.

Thus, it is possible to easily detect the abnormal state of the battery pack (41) including the plurality of cells (E1-En) or plurality of parallel cell blocks connected in series.

1. A battery abnormality detection system comprising:
a data acquirer structured to acquire voltage data and current data of each cell of a battery pack having a plurality of cells connected in series or of each parallel cell block of a battery pack having serially connected parallel cell blocks having a plurality of cells connected in parallel; and
an abnormality detector structured to detect a cell or parallel cell block in an abnormal state on the basis of a relative voltage change amount among the plurality of cells or among the plurality of parallel cell blocks in a constant voltage charging period.

2. The battery abnormality detection system according to claim 1, further comprising:
a representative value calculator structured to calculate a representative value of an amount of change in voltage of the plurality of cells or of the plurality of parallel cell blocks on the basis of each voltage change amount of the plurality of cells or the plurality of parallel cell blocks for a time between two points in the constant voltage charging period; and
a difference calculator structured to calculate a difference value between each voltage change amount of the plurality of cells or of the plurality of parallel cell blocks, and a representative value of the voltage change amount,
wherein the abnormality detector is structured to judge, to be in an abnormal state, a cell or parallel cell block having a voltage drop amount relative to the representative value of the voltage change amount exceeding a threshold value.

3. The battery abnormality detection system according to claim 2, wherein the representative value calculator is structured to use, as the representative value, a median value of a voltage change amount of the plurality of cells or a median value of a voltage change amount of the plurality of parallel cell blocks.

4. A battery abnormality detection method comprising:
a step of acquiring voltage data and current data of each cell of a battery pack having a plurality of cells connected in series or of each parallel cell block of a battery pack having serially connected parallel cell blocks having a plurality of cells connected in parallel; and
a step of detecting a cell or parallel cell block in an abnormal state on the basis of a relative voltage change amount among the plurality of cells or among the plurality of parallel cell blocks in a constant voltage charging period.

5. A non-transitory computer-readable recording medium having embodied thereon a battery abnormality detection program for causing a computer to execute processing comprising:
acquiring voltage data and current data of each cell of a battery pack having a plurality of cells connected in series or of each parallel cell block of a battery pack having serially connected parallel cell blocks having a plurality of cells connected in parallel; and
detecting a cell or parallel cell block in an abnormal state on the basis of a relative voltage change amount among the plurality of cells or among the plurality of parallel cell blocks in a constant voltage charging period.
